(19) United States
(12) Patent Application Publication
(10) Pub. No.: US 2024/0203782 A1
(43) Pub. Date: Jun. 20, 2024

(54) SUSCEPTOR AND METHOD OF MANUFACTURING THE SAME

(71) Applicant: MiCo Ceramics Ltd., Anseong-si (KR)

(72) Inventors: Min-Ho Ji, Anseong-si (KR); Gi-Myung Sung, Anseong-si (KR)

(21) Appl. No.: 18/538,038

(22) Filed: Dec. 13, 2023

(30) Foreign Application Priority Data
Dec. 14, 2022 (KR) 10-2022-0174914
Nov. 23, 2023 (KR) 10-2023-0164686

(51) Int. Cl. H01L 21/687; H01L 21/683

(52) U.S. Cl. CPC H01L 21/68714; H01L 21/6833

(57) ABSTRACT

The present disclosure provides a susceptor including a base member and an electrostatic chuck plate bonded to the base member by an adhesive layer, wherein the adhesive layer includes a plurality of spacers made of a first elastomer, and an adhesive made of a second elastomer, the adhesive filling a space between the spacers and bonding the base material and the electrostatic chuck plate to each other.

### CROSS-REFERENCE TO RELATED APPLICATION(S)

This application is based on and claims priority under 35 U.S.C. 119 to Korean Patent Applications Nos. 10-2022-0174914 and 10-2023-0164686 filed on Dec. 14, 2022 and Nov. 23, 2023, respectively, in the Korean Intellectual Property Office, the disclosure of which is herein incorporated by reference in its entirety.

### BACKGROUND

### 1. Field of the Invention

The present disclosure relates to a susceptor, and more specifically, to a susceptor for supporting a wafer in a semiconductor manufacturing process and a method of manufacturing the same.

### 2. Description of the Prior Art

Semiconductor devices or display devices are manufactured by laminating and patterning multiple thin film layers including dielectric layers and metal layers on a glass substrate, a flexible substrate, or a semiconductor wafer substrate through semiconductor processes such as a chemical vapor deposition (CVD) process, a physical vapor deposition (PVD) process, an ion implantation process, and an etching process. In a chamber for performing these semiconductor processes, a susceptor is used to support various substrates such as a glass substrate, a flexible substrate, and a semiconductor wafer substrate, and a representative example of the susceptor is an electrostatic chuck (ESC) that uses electrostatic force to fix a substrate.

In such an electrostatic chuck, a base and an electrostatic chuck plate bonded to the base have a predetermined cooling structure in order to uniformly cool a substrate on an electrostatic chuck plate by using an external cooling gas. Generally, the cooling structure is provided such that the cooling gas flow path provided in the base communicates with a gas hole provided in the electrostatic chuck plate.

Meanwhile, when bonding the base and the electrostatic chuck plate with an adhesive, a spacer is used to ensure a uniform adhesive thickness over the entire electrostatic chuck. Typically, spacers for electrostatic chucks are made of a polyimide film or ceramic material corresponding to a desired adhesive thickness.

The susceptors described above are usually used to support substrates at room temperature or high temperature. However, recently, there has been a growing need to perform a film forming process or an etching process while cooling a substrate to a cryogenic temperature of −50° ° C. or lower or −100° C. or lower.

In particular, as the difficulty in an etching process required for manufacturing semiconductor devices with a line width of 10 nm or less or 3D NAND flash devices increases due to the increase in semiconductor stacking height and decrease in circuit line width for ultra-fine semiconductor manufacturing, process issues such as a microbridge ((a defect in which portions that should not be etched are connected to each other due to a thinner line width) and polymer bottleneck phenomena occur frequently. To solve these process issues, cryogenic etching processes are being developed in which selectivity is improved and uniform etching is enabled even when an etching depth increases by lowering the temperature inside the chamber to −100° C. to minimize the movement of gases required for etching without polymers.

However, for conventional susceptors, use at such a cryogenic temperature is not considered, and there is very little consideration for securing reliable bonding characteristics between an electrostatic chuck plate and a base even in such a cryogenic situation.

### PRIOR ART DOCUMENTS

### Patent Documents

(Patent Document 0001) KR 2,288,530 B
(Patent Document 0002) JP 7,052,847 B

### SUMMARY

The inventors of the present disclosure have discovered that when using a conventional spacer 12 such as a polyimide film as illustrated in FIG. 1 to ensure a uniform adhesive thickness when bonding a base and an electrostatic chuck plate, cracks occurs in the electrostatic chuck plate when used for a long period of time in a cryogenic environment of −40° C.

The inventors of the present disclosure paid attention to the fact that polyimide spacers, which have a high clastic modulus and hardness but a low elongation and strain compared to a cryogenic adhesive such as a silicone resin, may cause stresses in electrostatic chuck plates depending on temperature changes experienced in applications in a wide temperature range, such as cryogenic applications. In other words, since the thermal stress generated in a material due to a difference in thermal expansion coefficient between material 1 and material 2 that are in close contact with each other is proportional to the elastic modulus (E) of the material, the difference in the thermal expansion coefficient difference between material 1 and material 2 (α1-α2), and the temperature difference (ΔT) according to the following Equation 1, a material with a higher elastic modulus experiences higher thermal stress.

$$Thermal stress = E ( α1 - α2 ) Δ T \qquad ( Equation 1 )$$

Therefore, it can be understood that, when bending is caused due to a difference in thermal expansion coefficient due to a temperature change, stress is concentrated in a plate portion to which a rigid spacer is bonded, causing peeling and/or cracking of the ceramic constituting the electrostatic chuck plate.

Therefore, the present disclosure provides a susceptor having an adhesive layer with good bonding properties even when used in a wide temperature range such as a cryogenic environment.

In addition, the present disclosure provides a susceptor that facilitates adjusting the thickness of an adhesive layer by using a spacer and exhibits a good bonding property over a wide use temperature range.

Furthermore, the present disclosure provides a method of manufacturing the above-described susceptor.

In order to solve the above-described technical problems, the present disclosure provides a susceptor including a base member; and an electrostatic chuck plate bonded to the base member by an adhesive layer, wherein the adhesive layer includes a plurality of spacers made of a first elastomer, and an adhesive made of a second elastomer, the adhesive filling a space between the spacers and bonding the base material and the electrostatic chuck plate to each other.

In the present disclosure, the first elastomer preferably includes a silicone resin. In addition, the second elastomer preferably includes a silicone resin.

In the present disclosure, the spacer may have an elastic modulus of 1 MPa to 3 MPa. In addition, the spacer may have an ultimate elongation of 150% to 300%.

In the present disclosure, one end portion of the spacer may be bonded to the electrostatic chuck plate to form a fixed end, and the other end portion may not be bonded to the base member to form a free end.

In addition, in the present disclosure, the ratio of the area occupied by the plurality of spaces to the area of the adhesive layer may be 0.1 to 5%.

In order to solve other technical problems, the present disclosure provides a method of manufacturing a susceptor by bonding a first base material and a second base material to each other, wherein the method may include operations of: manufacturing a plurality of pre-cured bodies made of a first elastomer; forming a plurality of spacers on the first base material by bonding the plurality of pre-cured bodies to the first base material; applying an adhesive made of a second elastomer to a space between the plurality of spacers on the first base material; and adhering the second base material to the first base material.

In the present disclosure, the first base material may be an electrostatic chuck plate, and the second base material may be a base member.

At this time, the first elastomer and the second elastomer preferably include a silicone resin.

In addition, the operation of forming the plurality of spacers may include an operation of completely curing the plurality of pre-cured bodies after bonding the plurality of pre-cured bodies to the first base material.

In addition, in the applying of the adhesive, the adhesive made of the second elastomer preferably has a height less than or equal to a height of the spacer.

According to the present disclosure, it is possible to provide a susceptor having an adhesive layer with good bonding properties even when used in a wide temperature range such as a cryogenic environment.

In addition, according to the present disclosure, it is possible to provide a susceptor that exhibits a good bonding property over a wide use temperature range despite the use of a spacer.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a photograph showing cracks generated in an electrostatic chuck plate in a cryogenic environment when a conventional spacer was used;

FIG. 2 is a view schematically illustrating a cross section of a susceptor according to an embodiment of the present disclosure;

FIG. 3 is a view schematically illustrating a stress-strain curve;

FIG. 4 is a view schematically illustrating the arrangement of spacers according to an embodiment of the present disclosure;

FIG. 5 is a flowchart sequentially illustrating each processes of a spacer manufacturing method according to an embodiment of the present disclosure;

FIG. 6 is a photograph of pre-cured spacers made of a silicone resin manufactured according to an embodiment of the present disclosure;

FIG. 7 is a flowchart schematically illustrating a bonding process of adhering an electrostatic chuck plate and a base member to each other according to an embodiment of the present disclosure; and

FIG. 8 is a view illustrating a stress-strain curve of a spacer manufactured according to an embodiment of the present disclosure.

### DETAILED DESCRIPTION OF THE EXEMPLARY EMBODIMENTS

Unless otherwise defined, all technical and scientific terms used in this specification have the same meaning as commonly understood by a person ordinarily skilled in the art to which the present disclosure pertains. In general, the nomenclature used herein is well known and commonly used in the art.

Throughout this specification, when a part is described to “include” a certain component, this means that the part may further include other components rather than excluding other components, unless specifically stated to the contrary. In addition, in this specification, the expression “being made of material A” means not only consisting of only the material A, but also being mixed with materials other than the material A or allowing use of materials obtained by synthesizing materials other than the material A while including the material A as a main component (a component equal to or greater than 50% by weight).

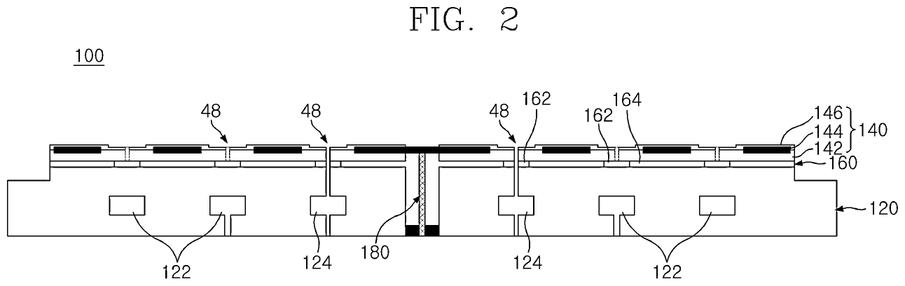

FIG. 2 is a cross-sectional view illustrating a structure of an electrostatic chuck 100 according to an embodiment of the present disclosure.

Referring to FIG. 2, the electrostatic chuck 100 according to an embodiment of the present disclosure includes a lower base member 120 and an upper electrostatic chuck plate 140. The electrostatic chuck 100 is preferably of a circular type, but in some cases, may be designed in another shape such as oval or square.

The base member 120 may be configured as a multi-layer structure including a plurality of metal layers. These metal layers may be bonded through a brazing process, a welding process, a bonding process, or the like.

In the present disclosure, the electrostatic chuck plate 140 may include an electrode layer 144. For example, the electrostatic chuck plate may have a stacked structure of an insulating layer 142, an electrode layer 144 on the insulating layer 142, and a dielectric layer 146 on the electrode layer 144, but the present disclosure is not limited thereto.

In the present disclosure, the insulating layer 142 may be made of a ceramic material. In an embodiment, the insulating layer 142 may be made of at least one material selected from a group consisting of alumina (Al₂O₃), aluminum nitride (AlN), silicon carbide (SiC), silicon nitride (Si₃N₄), silicon oxide (SiO₂), barium oxide (BaO), zinc oxide (ZnO), cobalt oxide (CoO), tin oxide (SnO₂), zirconium oxide (ZrO₂), ytria (Y₂O₃), and an yttrium aluminate such as YAG, YAM, or YAP.

In the present disclosure, the electrode layer 144 is made of a conductive metal material, and is connected to a connector 180 to be supplied with power from the outside of the electrostatic chuck. As an example, the electrode layer 144 may be made of at least one of silver (Ag), gold (Au), nickel (Ni), tungsten (W), molybdenum (Mo), and titanium (Ti), and may be made of tungsten (W). In the present disclosure, the electrode layer 144 may be formed through a thermal spray coating process or a screen printing process.

The electrode layer 144 may receive a bias power when a substrate (not illustrated) to be placed on top of the dielectric layer 146 is loaded, and may generate electrostatic force to control chucking. When a substrate (not shown) is unloaded, dechucking may be performed by applying an opposite bias power to the electrode layer 320 to cause discharge.

In the present disclosure, the dielectric layer 146 may be made of a ceramic material. In an embodiment, the dielectric layer 146 may be made of the same material as that of the above-described insulating layer 142. For example, the dielectric layer may be made of one material selected from among aluminum oxide (Al₂O₃), aluminum nitride (AlN), silicon carbide (SiC), silicon nitride (Si₃N₄), silicon oxide (SiO₂), barium oxide (BaO), zinc oxide (ZnO), cobalt oxide (CoO), tin oxide (SnO₂), zirconium oxide (ZrO₂), Y₂O₃, and an yttrium aluminate such as YAG, YAM, or YAP.

In the present disclosure, the electrostatic chuck plate 140 including the insulating layer 142 and the dielectric layer 146 may have a stacked structure of ceramic sheets. For example, the electrostatic chuck plate 140 may be formed by stacking a plurality of ceramic green sheets forming the electrode layer 144 and then sintering them, or by stacking a plurality of ceramic sintered body sheets forming the electrode layer 144 and then bonding the sheets to each other by sintering. Alternatively, of course, part or all of the insulating layer 142 and/or the dielectric layer 146 may be formed through coating, such as plasma spraying or aerosol deposition, of a ceramic material.

In the present disclosure, the electrostatic chuck plate 140 is bonded to the base member 120 via an adhesive layer.

As illustrated, an adhesive layer 160 is provided between the electrostatic chuck plate and the base member for adhesion or bonding of the electrostatic chuck plate and the base member. The adhesive layer 160 includes a plurality of spacers 162 to maintain the gap between the electrostatic chuck plate and the base member. In addition, an adhesive 164 for bonding the electrostatic chuck plate and the base member to each other is applied to areas of the adhesive layer other than the areas where the spacers 162 are disposed.

In the present disclosure, each spacer 162 may have a three-dimensional shape with a predetermined thickness between two opposite surfaces, such as the top and bottom surfaces. In the present disclosure, the top and bottom surfaces of the spacers are portions that are in contact with the electrostatic chuck plate and the base member, respectively, and define the contact areas with the base materials (the electrostatic chuck plate and the base member).

In the present disclosure, the contact area of each spacer may be appropriately designed in consideration of the bonding strength with the electrostatic chuck plate or the base member, which is the base material to which the spacer is attached. For example, in the present disclosure, the contact area of the spacer is preferably 1 mm² or more, wherein, when the contact area of the spacer is less than 1 mm², it is difficult to provide adequate bonding strength to ensure that the spacer is fixed to the base material and maintain the thickness.

Meanwhile, in the present disclosure, the total contact area of the spacers included in the adhesive layer of the electrostatic chuck may be designed in consideration of the following factors.

When the sum of the contact areas of all spacers is small, it becomes difficult to secure an adhesive layer with a uniform thickness throughout the electrostatic chuck. In contrast, as will be described later, since the spacers of the present disclosure are provided in a pre-cured or fully cured state, the spacers cannot substantially contribute to the bonding between the electrostatic chuck plate and the base member. Therefore, as the total area of the spacers increases, the bonding strength between the electrostatic chuck plate and the base member decreases.

In the present disclosure, the ratio of the total area occupied by the spacers to the total adhesive layer area (hereinafter, referred to as an “area ratio”) is preferably 0.05% or more, 0.1% or more, 0.15% or more, 0.2% or more, or 0.25% or more. In addition, the area ratio is preferably 10% or less, 5% or less, 4% or less, 3% or less, 2% or less, or 1% or less.

In the present disclosure, the spacers may be implemented by an elastomer having a low elastic modulus and high ultimate elongation.

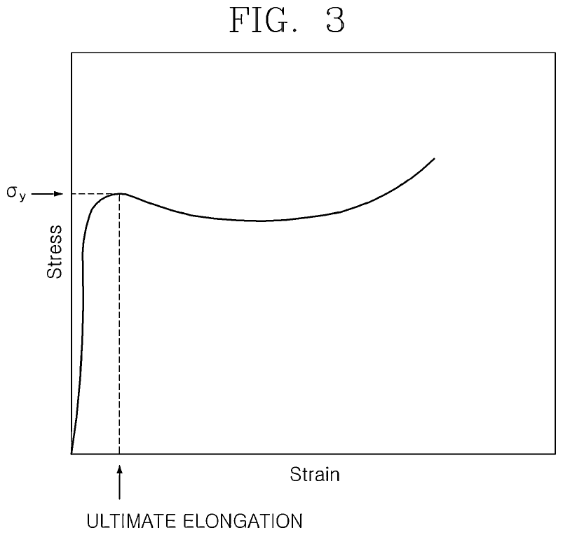

In the specification of the present disclosure, the term “ultimate elongation” means the maximum strain that can be obtained before the limit of fracture when a load is applied to a material, and may be expressed as a strain value at a yield stress oy in a stress-strain curve. In addition, elastic modulus refers to a coefficient that represents the relationship between the stress, which is a force applied to a material with linear elasticity, and the strain of the material, and is also called a Young's modulus. The elastic modulus and elongation are shown in FIG. 3. In the present disclosure, when the elastic section of the stress-strain curve cannot be treated as a strictly linear section, the elastic modulus or Young's modulus means a value calculated by a general mathematical approximation method such as a least-squares method.

Meanwhile, in the present disclosure, when there is no special temperature reference for the elastic modulus and ultimate elongation, the values of the elastic modulus and ultimate elongation mean the values at −70° C.

In the present disclosure, the elastic modulus of the spacers may be 1.0 MPa or more, 1.5 MPa or more, 1.6 MPa or more, 1.7 MPa or more, 1.8 MPa, or 1.9 MPa or more. In addition, the elastic modulus of the spacers may be 5.0 MPa or less, 4.0 MPa or less, 3.0 MPa or less, 2.9 MPa or less, and 2.8 MPa or less.

In addition, in the present disclosure, the ultimate elongation of the spacers may be 150% or more, 200% or more, 250% or more, or 300% or more. In addition, the ultimate elongation of the spacers may be 400% or less, 380% or less, or 350% or less.

Preferably, as the elastomer, at least one polymer selected from the group consisting of a silicone resin (or silicone rubber), butadiene, a copolymer of styrene and acrylonitrile, butyl rubber, and fluorine rubber may be used.

In the present disclosure, the elastomer is preferably a silicone resin. The silicone resin may have a molecular structure in which at least one of a methyl group, an ethyl group, a propyl group, a butyl group, a phenyl group, and a hexyl group is bonded to a siloxane skeleton. For example, silicone rubber containing a phenyl group in a side chain is suitable for use at a cryogenic temperature of −50° C. or lower.

For example, in the present disclosure, the silicone resin may be phenyl vinyl methyl silicone (PVMQ) silicone containing a phenyl group in a polymer chain. In addition, of course, in the present disclosure, the silicone resin may be a two-component room temperature vulcanizing (RTV) product separated into a base material and a curing agent.

In the present disclosure, the elastomer may be one in which inorganic powder is dispersed on an elastomeric matrix. As an example, in the present disclosure, one material selected from among alumina (Al₂O₃), aluminum nitride (AlN), silicon carbide (SiC), silicon nitride (Si₃N₄), silicon oxide (SiO₂), barium oxide (BaO), zinc oxide (ZnO), cobalt oxide (CoO), tin oxide (SnO₂), zirconium oxide (ZrO₂), Y₂O₃, and an yttrium aluminate material such as YAG, YAM, or YAP may be used as the inorganic powder.

In the present disclosure, the spacers are deformed when stress occurs in the electrostatic chuck plate or the base member in a cryogenic or ultra-low temperature range of −50° C. or −100° C. or lower, thereby relieving this stress. Accordingly, the spacers are able to relieve the stress generated at an adhesive interface between the electrostatic chuck plate and the base member operating at a cryogenic temperature while performing the original function thereof.

Meanwhile, in the present disclosure, the same elastomer as that described as the material of the spacers may be used as the adhesive constituting the adhesive layer. Preferably, as the adhesive, a silicone resin may be used and more preferably, a silicone resin containing a phenyl group in a side chain may be used.

In addition, the silicone resin may be a silicone resin in which inorganic powder is dispersed, as described in relation to the spacers.

In addition, according to another aspect of the present disclosure, from the viewpoint of relieving thermal stress generated between the spacers constituting the adhesive layer and the adhesive material, the spacers and the adhesive material may be made of the same elastomer. Of course, the present disclosure is not limited thereto.

Meanwhile, in the present disclosure, the spacers constituting a part of the adhesive layer may be mounted to maintain a bonded state with either the electrostatic chuck plate or the base member. In this case, the non-bonded ends of the spacers exist as free ends that are not fixed, thereby providing an advantageous structure for relieving stress generated on the sides of the bonded fixed ends.

In this regard, in view of the fact that since the base member usually contains a large amount of metal components such as aluminum, aluminum metal alloy, or aluminum-ceramic composite, the base member is made of an advantageous material for relieving generated stress and has a high coefficient of thermal expansion, which can cause large deformation in the spacers, it is preferable for the spacers to maintain the state of being bonded with the electrostatic chuck plate. That is, the top surfaces of the spacers are bonded to the electrostatic chuck plate to form fixed ends, while the bottom surfaces of the spacers form ends that are not bonded to the base member, i.e., free ends, whereby the spacers are able to provide a structure more advantageous for relieving stress generated in the electrostatic chuck plate.

Referring again to FIG. 2, in order to uniformly cool the substrate (e.g., a glass substrate, a flexible substrate, a semiconductor wafer substrate, or the like) on the electrostatic chuck plate 140 by using an external cooling gas, the base member 120 is provided with a cooling gas flow path 124 that provides a passage for the flow of a base cooling gas. A plurality of gas holes 48 are formed on the surface of the electrostatic chuck plate 140 to communicate with the cooling gas flow path 124 to spray the cooling gas above the dielectric layer 146.

In the drawing, the cooling gas flow path 124 is illustrated to be vertically connected to the gas holes 48, but this arrangement is exemplary and the present disclosure is not limited thereto. In addition, in the present disclosure, the cooling gas flow path 124 is connected through the adhesive layer 160, in which case, of course, the cooling gas flow path 124 can be connected to the gas holes 48 by penetrating the adhesive layer, especially the spacers 162.

Meanwhile, the base member 120 is provided with a coolant flow path 124 through which coolant circulates to adjust the temperature of the base member 120. The coolant flow path 124 may be provided with an inlet through which the coolant flows in from the outside of the base member and an outlet through which the circulated coolant flows out.

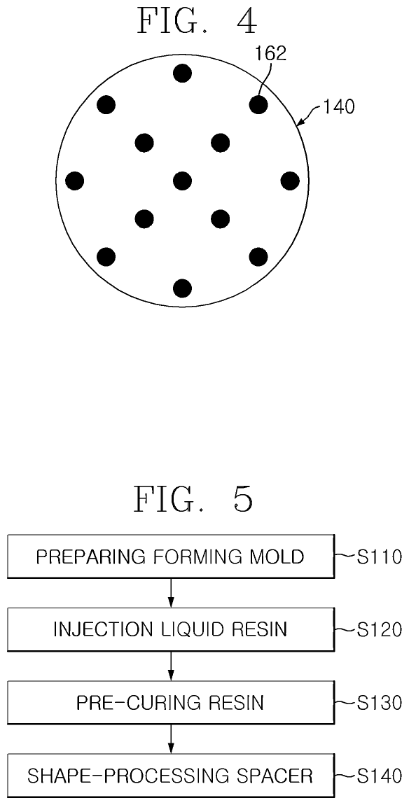

FIG. 4 is a view schematically illustrating the arrangement of spacers according to an embodiment of the present disclosure.

Referring to FIG. 4, the spacers are evenly distributed from the center to the outer periphery of the electrostatic chuck plate 140.

As illustrated, the spacers may be distributed radially, but this is only an example, and of course, the spacers may be arranged in various ways.

Hereinafter, a method of manufacturing an electrostatic chuck according to an embodiment of the present disclosure will be described.

FIG. 5 is a flowchart sequentially illustrating each processes of a spacer manufacturing method according to an embodiment of the present disclosure.

Referring to FIG. 5, a forming mold for molding the spacers are prepared (S110). Any mold having the shape of the spacers may be used as a forming mold. In addition, the forming mold may be a mold for forming a plurality of spacers at once.

Next, a liquid resin is injected into the forming mold (S120). The above-described elastomers may be used as the liquid resin. For example, as the resin, at least one polymer selected from among the group consisting of a silicone resin (or silicone rubber), butadiene, a copolymer of styrene and acrylonitrile, butyl rubber, and fluorine rubber may be used. For example, a silicone resin may be used.

Next, the injected liquid resin is pre-cured (S130). Various methods such as heat curing, photo curing, or curing using a curing agent may be used as the curing method. For example, when the liquid resin is a silicone resin, the resin may be pre-cured by maintaining the liquid resin at a temperature ranging from room temperature to 60° C. for a predetermined period of time. Meanwhile, additionally, during the pre-curing process, a predetermined pressure (e.g., 1 to 20 kgf/cm) may be added to adjust the thickness or size of the pre-cured body.

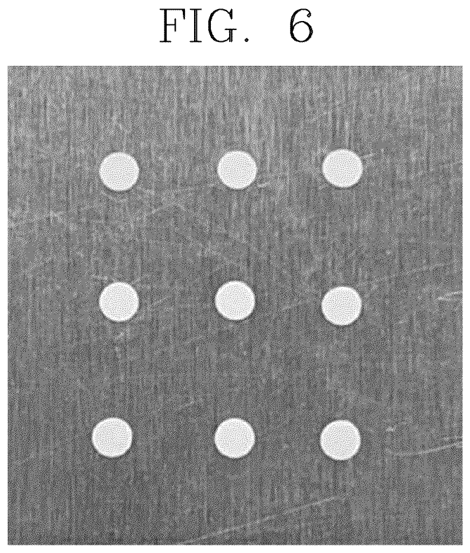

Finally, the pre-cured body is processed to a desired thickness and size to manufacture pre-cured spacers (S140). FIG. 6 is a photograph of manufactured pre-cured spacers made of a silicone resin.

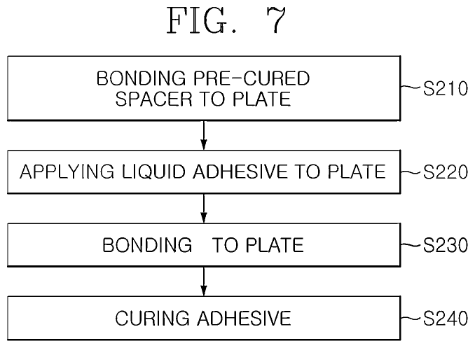

FIG. 7 is a flowchart schematically illustrating a bonding process of adhering an electrostatic chuck plate and a base member to each other by using manufactured pre-cured spacers.

Referring to FIG. 7, first, the pre-cured spacers are bonded to the electrostatic chuck member (S210). At this time, the member to which the pre-cured spacers are to be bonded may be either the electrostatic chuck plate or the base member. For example, the member to which the pre-cured spacers are to be attached may be the electrostatic chuck plate. As described above, the pre-cured spacers have a predetermined bending strength so that the pre-cured spacers can be firmly bonded to the electrostatic chuck plate. After being firmly bonded to the electrostatic chuck plate, the spacers can be completely cured by a curing method such as heat- or photo-curing.

Next, a liquid adhesive is applied to the electrostatic chuck plate to which the spacers are bonded. As described above, the liquid adhesive is preferably an elastomer, and as the elastomer, at least one polymer selected from the group consisting of a silicone resin (or silicone rubber), butadiene, a copolymer of styrene and acrylonitrile, butyl rubber, and fluorine rubber may be used. Preferably, the liquid adhesive may be a silicone resin.

In the application operation, application height of the liquid adhesive is preferably equal to or smaller than the height of the spacers, which may be a way to prevent the liquid adhesive from being applied to the surfaces of the spacers.

Next, the electrostatic chuck plate and the base member applied with the liquid adhesive are bonded to each other (S230). This bonding operation may be conducted under pressure to maintain a desired bonding thickness.

Next, bonding between the electrostatic chuck plate and the base member is completed through heat-curing, photo-curing, or curing using a curing agent.

### Spacer Manufacturing Example 1

A two-component PVMQ silicone resin was injected into the mold and pre-cured at room temperature for 20 hours, and then dog-bone-shaped spacers were molded. After molding the spacers, the spacers were completely cured at a temperature of 120° C. for 1 hour, and a spacer test sample was manufactured. The specifications of the used silicone resin are as follows.
elongation (room temperature): 290%
clastic modulus of elasticity (room temperature): 2.3 MPa
shear strength (room temperature): 2 MPa

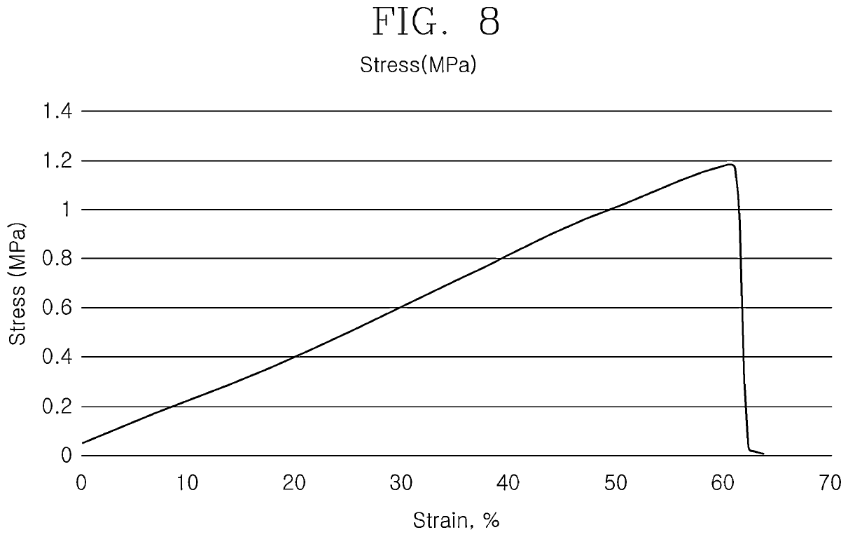

The stress-strain characteristics of the cured spacer test sample were measured, and the results are shown in FIG. 8. The measured and calculated breaking stress, elastic modulus, and ultimate elongation are shown in Table 1 below.

TABLE 1

| | Yield Stress σ_{y} | Elastic Modulus E | Ultimate Elongation |
|---|---|---|---|
| Sample | (MPa) | (MPa) | (%) |
| #1 | 6.01 | 2.68 | 225 |
| #2 | 6.44 | 2.34 | 275 |
| #3 | 7.32 | 1.95 | 376 |
| #4 | 7.32 | 2.08 | 353 |
| #5 | 6.32 | 2.58 | 246 |

### Spacer Manufacturing Example 2

A spacer test specimen was manufactured in the same manner as Manufacturing Example 1, except that two-component polymethylsiloxane silicone (MQ) was used as the silicone resin. The stress-strain characteristics of the cured spacer test sample were measured. The measured and calculated breaking stress, elastic modulus, and ultimate elongation are shown in Table 2 below.

TABLE 2

| | Yield σ_{y} | Elastic Modulus E | Ultimate Elongation |
|---|---|---|---|
| Sample | (MPa) | (MPa) | (%) |
| #1 | 1.84 | 6.39 | 28.73 |
| #2 | 1.71 | 5.54 | 30.82 |
| #3 | 2.27 | 5.86 | 38.73 |
| #4 | 1.92 | 5.56 | 34.57 |

### Electrostatic Chuck Plate Bonding Example

As in Manufacturing Example 1, a liquid silicone resin was injected into the mold and pre-cured at room temperature for 20 hours, and then a Φ3 mm spacer was molded.

40 molded spacers were bonded to the electrostatic chuck plate of Φ300 mm with a radial arrangement as illustrated in FIG. 4. Next, the spacers were fully cured in air. The thickness of the fully cured spacers was approximately 300 μm.

Next, a liquid silicone resin was applied to the electrostatic chuck plate to which the spacers were bonded to substantially the same height as the spacers, and the silicone resin was prevented from being applied to the surfaces of the spacers. At this time, the liquid silicone resin made of the same material as the spacers was used.

Next, the spacers applied with the liquid silicone resin was bonded to the base member, and the silicone resin was maintained at a temperature of 120° C. for 10 hours to be completely cured, thereby manufacturing an electrostatic chuck plate.

The manufactured electrostatic chuck plate was cooled to a temperature of −40° C., and the bonded state was observed. Although cracks occurring on the surface of the ceramic plate can be observed with the naked eye, the occurrence of cracks was observed by using ultrasonic inspection equipment in order to identify invisible cracks.

### Comparative Example

40 Φ3 mm polyimide spacers having a thickness of 300 micrometers were bonded to a @300 mm electrostatic chuck plate by using a silicone tape adhesive.

Next, a liquid silicone resin was applied to the electrostatic chuck plate to which the spacers were bonded to substantially the same height as the spacers, and the silicone resin was prevented from being applied to the surfaces of the spacers. At this time, the liquid silicone resin made of the same material as the spacers was used.

Next, the spacers applied with the liquid silicone resin were bonded to the base member, and the silicone resin was maintained at a temperature of 120° C. for 10 hours to be completely cured, thereby manufacturing an electrostatic chuck plate.

The manufactured electrostatic chuck plate was cooled to a temperature of −40° ° C., and the bonded state was observed.

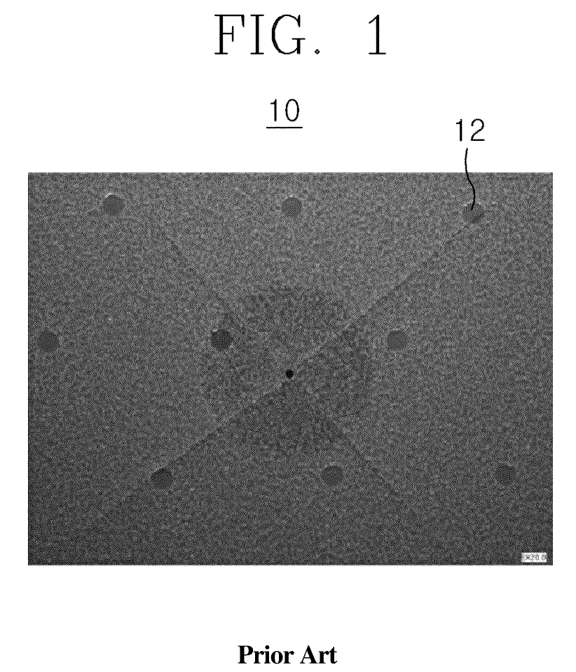

As a result of observation after cooling, it was identified that no cracks occurred in the plate in the embodiment, but in the Comparative Example, cracks occurred on the plate as in FIG. 1.

Although the present disclosure has been described above with reference to exemplary embodiments and drawings, the embodiments and drawings were provided only to facilitate a more general understanding of the present disclosure, and the present disclosure is not limited to the above embodiments. A person ordinarily skilled in the art to which the present disclosure pertains may be aware that various changes and modifications can be made without departing from the essential characteristics of the present disclosure. Therefore, the spirit of the present disclosure should not be limited to the described embodiments, and not only the claims, but also all technical ideas equivalent to or equivalently modified to the claims should be interpreted as being included in the scope of the present disclosure.

What is claimed is:

1. A susceptor comprising:
a base member, and
an electrostatic chuck plate bonded to the base member via an adhesive layer,
wherein the adhesive layer comprises:
a plurality of spacers made of a first elastomer; and
an adhesive made of a second elastomer, the adhesive filling a space between the spacers and bonding the base member and the electrostatic chuck plate to each other.

2. The susceptor of claim 1, wherein the first elastomer comprises a silicone resin.

3. The susceptor of claim 1, wherein the second elastomer comprises a silicone resin.

4. The susceptor of claim 1, wherein the spacer has an elastic modulus of 1 MPa to 3 MPa.

5. The susceptor of claim 1, wherein the spacer has an ultimate elongation of 150% to 300%.

6. The susceptor of claim 1, wherein one end portion of the spacer is bonded to the electrostatic chuck plate to form a fixed end, and a remaining end portion is not bonded to the base member to form a free end.

7. The susceptor of claim 1, wherein a ratio of an area occupied by the plurality of spaces to an area of the adhesive layer is 0.1 to 5%.

8. A method of manufacturing a susceptor by bonding a first base material and a second base material to each other, the method comprising:
manufacturing a plurality of pre-cured bodies made of a first elastomer,
forming a plurality of spacers on the first base material by bonding the plurality of pre-cured bodies to the first base material;
applying an adhesive made of a second elastomer to a space between the plurality of spacers on the first base material; and
adhering the second base material to the first base material.

9. The method of claim 8, wherein the first base material is an electrostatic chuck plate, and
the second base material is a base member.

10. The method of claim 8, wherein the first elastomer and the second elastomer include a silicone resin.

11. The method of claim 8, wherein the forming of the plurality of spacers comprises:
completely curing the plurality of pre-cured bodies after bonding the plurality of pre-cured bodies to the first base material.

12. The method of claim 8, wherein the spacer has an elastic modulus of 1 MPa to 3 MPa.

13. The method of claim 8, wherein the spacer has an ultimate elongation of 150% to 300%.

14. The method of claim 8, wherein, in the applying of the adhesive, the adhesive made of the second elastomer has a height less than or equal to a height of the spacer.
